(19) United States
(12) Patent Application Publication
(10) Pub. No.: US 2025/0259854 A1
(43) Pub. Date: Aug. 14, 2025

(54) PATTERN FORMATION METHOD AND METHOD OF MANUFACTURING ARTICLE

(71) Applicant: CANON KABUSHIKI KAISHA, Tokyo (JP)

(72) Inventors: RYOSUKE HAMAMOTO, Tochigi (JP); TOSHIKI ITO, Kanagawa (JP)

(21) Appl. No.: 19/023,608

(22) Filed: Jan. 16, 2025

(30) Foreign Application Priority Data
Feb. 14, 2024 (JP) 2024-020058

(51) Int. Cl. H01L 21/311; G03F 7/00

(52) U.S. Cl. CPC H01L 21/31116; G03F 7/0002; H01L 21/31138; H01L 21/31144

(57) ABSTRACT

A pattern formation method includes: forming a first inversion layer on a projecting and recessed pattern of a curable composition; forming a flattened inversion layer as a second inversion layer on the first inversion layer; performing first etching of etching an upper layer portion of an inversion layer including the first inversion layer and the flattened inversion layer to expose a top surface of a projecting portion of the projecting and recessed pattern; and performing second etching of etching the exposed pattern of the curable composition using the inversion layer remaining in a recessed portion of the projecting and recessed pattern as a mask, and in the first etching, the first inversion layer and the flattened inversion layer are etched using mixed gas obtained by a plurality of kinds of etching gas.

### BACKGROUND OF THE INVENTION

### Field of the Invention

The present invention relates to a pattern formation method, a method of manufacturing an article, and the like.

### Description of the Related Art

There has been increased demand for miniaturization of semiconductor devices, MEMS, and the like, and an imprint technology of molding an imprint material on a substrate with a mold and forming a pattern of the imprint material on the substrate has attracted attention in addition to the photolithography technology in the related art.

According to the imprint technology, projecting and recessed patterns of the mold are formed by bringing the imprint material applied to the substrate into contact with the mold. It is possible to apply a step called an inversion process in order to work the substrate using, as a mask, the pattern obtained using the imprint technology.

Japanese Patent Laid-Open No. 2016-162862 discloses inversion process steps as follows. First, an inversion layer is formed on a projecting and recessed pattern (inversion layer formation step), and an inversion layer material is embedded in recessed portions. At this time, the inversion layer material is also stacked on tops of the projecting portions of the projecting and recessed pattern to form an excess inversion layer. Therefore, the excess inversion layer is removed (excess inversion layer removal step) such that top surfaces of the projecting portions of the projecting and recessed pattern of a cured film of a curable composition are exposed to thereby expose the inversion layer embedded in the recessed portions. Thereafter, a remaining film of the projecting and recessed pattern (remaining film etching step) and further a worked layer located below the remaining film are etched using the exposed inversion layer as a mask to thereby form an inverted pattern (worked layer working step).

It is desirable that the inversion layer have been smoothed beforehand in such an inversion process step. Japanese Patent Laid-Open No. 2018-98470 has proposed a method of smoothing an inversion layer by forming the inversion layer by an inkjet method and a method of smoothing the inversion layer by further pressing the inversion layer with a planar mold in order to obtain desired smoothness of the inversion layer.

However, according to the method in Japanese Patent Laid-Open No. 2018-98470, physical properties of materials are limited in order to address the inkjet method and to smooth the inversion layer through pressing with a mold with a smooth surface. If priority is placed on addressing the limit, a situation in which etching durability of the inversion layer to function as a mask cannot sufficiently be obtained may occur in a stage in which the inversion layer is used as a mask to remove the remaining film of the projecting and recessed pattern (remaining film etching step). Furthermore, a similar problem may also occur in a stage in which the worked layer located below the inversion layer is etched to form the inverted pattern (worked layer working step). Therefore, according to the method in Japanese Patent Laid-Open No. 2018-98470, there is a need to select materials that have both material physical properties suitable for the inkjet method and the planar mold pressing and material physical properties to have etching durability, and a degree of freedom in selecting usable materials may decrease. Furthermore, in a case where materials are newly developed, the development will be carried out in a low degree of freedom, the development may be highly difficult, and cost may become problematic.

### SUMMARY OF THE INVENTION

According to an embodiment of the present invention, a pattern formation method includes: forming a first inversion layer on a projecting and recessed pattern of a curable composition; forming a flattened inversion layer as a second inversion layer on the first inversion layer; performing first etching of etching an upper layer portion of an inversion layer including the first inversion layer and the flattened inversion layer to expose a top surface of a projecting portion of the projecting and recessed pattern; and performing second etching of etching the exposed pattern of the curable composition using the inversion layer remaining in a recessed portion of the projecting and recessed pattern as a mask, and in the first etching, the first inversion layer and the flattened inversion layer are etched using mixed gas obtained by a plurality of kinds of etching gas.

Further features of the present invention will become apparent from the following description of embodiments with reference to the attached drawings.

### BRIEF DESCRIPTION OF THE DRAWINGS

FIGS. 1A to 1D are schematic diagrams illustrating a flow of inversion process steps according to a first embodiment.

FIGS. 2A to 2D are schematic diagrams illustrating a flow of the inversion process steps according to the first embodiment.

FIG. 3 is a diagram illustrating an example of an etching rate with respect to a mixing ratio of etching gas according to the first embodiment.

FIG. 4 is a flowchart for explaining an inversion layer formation step according to a second embodiment.

FIGS. 5A to 5F are schematic diagrams illustrating known inversion process steps.

FIGS. 6A to 6D are schematic diagrams for explaining adverse effects that may occur in the inversion process steps.

FIG. 7 is a flowchart for explaining an arrangement step.

FIGS. 8A to 8D are schematic diagrams for explaining an optical nanoimprint method.

### DESCRIPTION OF THE EMBODIMENTS

Hereinafter, with reference to the accompanying drawings, favorable modes of the present invention will be described using Embodiments. In each diagram, the same reference signs are applied to the same members or elements, and duplicate description will be omitted or simplified.

### <Inversion Process Steps>

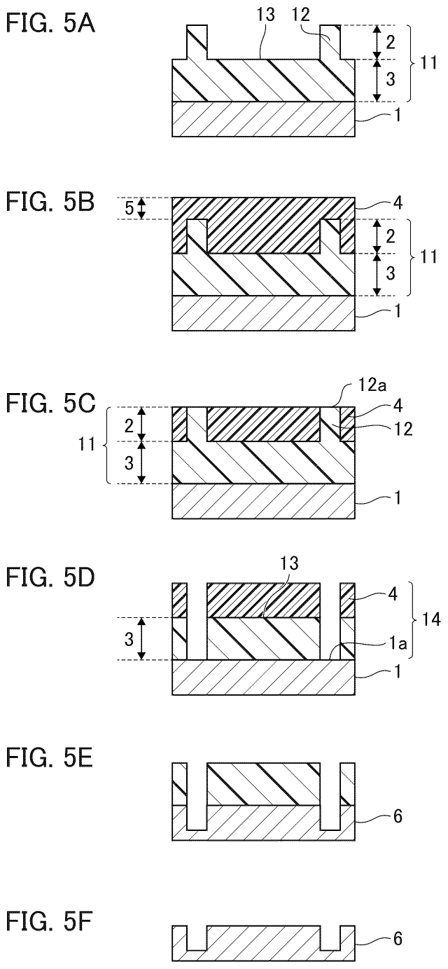

FIG. 5 is a schematic diagram illustrating known inversion process steps. The inversion process steps will be described using the drawing. FIG. 5A is a schematic diagram illustrating an initial cured film formation step. In the inversion process steps, a projecting and recessed pattern 2 of a curable composition including a projecting portion 12 and a recessed portion 13 is formed on a substrate 1 as schematically illustrated in FIG. 5A as the initial cured film formation step. In other words, it is possible to state that the initial cured film formation step is a projecting and recessed pattern formation step. Hereinafter, the resulting object formed here will be referred to as a cured film 11. Also, a part (base part) below the projecting and recessed pattern 2 in the cured film 11 as illustrated in FIG. 5A will be referred to as a remaining film 3. The remaining film 3 is not necessary in an etching step after the pattern formation, thus needs to be removed, and is to be removed in a later step. Examples of a method of forming the cured film 11 with the projecting and recessed pattern 2 on the substrate 1 in the initial cured film formation step include an optical nanoimprint method and photolithography. Although the projecting and recessed pattern 2 is formed by the optical nanoimprint method as an example in the present embodiment, the present invention is not limited thereto. Details of the optical nanoimprint method will be described later.

As the substrate 1, a silicon wafer is used, for example. The substrate 1 may additionally include a worked layer on its surface, and another layer may be further formed below the worked layer. Also, as the substrate 1, it is possible to arbitrarily select a substrate known as a semiconductor device substrate of aluminum, a titanium-tungsten alloy, an aluminum-silicon alloy, an aluminum-copper-silicon alloy, silicon oxide, silicon nitride, and the like as well as the silicon wafer. Note that adhesiveness of the worked layer on the outermost layer of the substrate 1 to the curable composition may be improved through silane coupling treatment, silazane treatment, or surface treatment such as formation of an organic thin film.

In the present embodiment, the curable composition is a composition containing at least a polymerizable compound and a polymerization initiator. Also, the curable composition may further contain a non-polymerizable compound or a solvent as needed. The non-polymerizable compound is at least one kind selected from a group consisting of a sensitizer, a hydrogen doner, an internal mold release agent, a surfactant, an antioxidant, a polymer component, and the like. In the present embodiment, it is assumed that a certain worked layer is provided on the substrate. In the initial cured film formation step, an arrangement step to a release step, which will be described later, are performed on the worked layer on the substrate 1 using a curable composition (a) in which the content of inorganic element is equal to or less than 1% by weight, or preferably a curable composition (a) that does not contain inorganic elements such as silicon atoms. In this manner, it is possible to form the cured film 11 with a pattern including the projecting portion 12 and the recessed portion 13 on the substrate 1. Although it is possible to use curable compositions described in Japanese Patent Laid-Open No. 2016-162862, for example, as the curable composition (a), the present invention is not limited thereto.

FIG. 5B is a schematic diagram illustrating an inversion layer formation step. The inversion layer formation step is performed after the initial cured film formation step. In the inversion layer formation step, the inversion layer 4 is formed on the cured film 11 with the formed projecting and recessed pattern 2. Since the inversion layer 4 is used as a mask to etch the cured film 11 in a remaining film etching step, which will be described later, the inversion layer 4 is required to have a sufficient etching selection ratio between itself and the curable composition forming the cured film 11. At this time, the inversion layer 4 which is an upper layer of the cured film 11 and is located above the projecting portion 12 as in the drawing will be referred to as an excess inversion layer 5.

FIG. 5C is a schematic diagram illustrating an excess inversion layer removal step. The excess inversion layer removal step is performed after the inversion layer formation step. In the excess inversion layer removal step, the excess inversion layer 5 is removed. Specifically, the inversion layer 4 (excess inversion layer 5) is removed until the upper portion (top surface 12a) of the projecting portion 12 of the cured film 11 with the projecting and recessed pattern 2 is exposed. FIG. 5C illustrates a state where the inversion layer 4 (excess inversion layer 5) has been removed and the top surface 12a of the projecting portion 12 is exposed.

FIG. 5D is a schematic diagram illustrating a remaining film etching step. The remaining film etching step is performed after the excess inversion layer removal step. In the remaining film etching step, the remaining film 3 of the cured film 11 is removed. In the remaining film etching step, the inversion layer 4 remaining in the recessed portion 13 of the projecting and recessed pattern 2 in the excess inversion layer removal step is used as a working mask. Etching is similarly performed with the working mask by starting the projecting portion 12 of the projecting and recessed pattern 2 exposed after the inversion layer 4 is removed in the excess inversion layer removal step. The etching is continued until a worked layer surface 1a of the substrate 1 is exposed, and a pattern with projections and recesses inverted from those of the projecting and recessed pattern 2 of the curable composition (hereinafter, an inverted pattern 14) is formed on the worked layer. FIG. 5D illustrates a state where the remaining film 3 has been etched and the inverted pattern 14 is formed on the worked layer.

FIG. 5E is a schematic diagram illustrating a worked layer working step. The worked layer working step is performed after the remaining film etching step. In the worked layer working step, the inverted pattern is transferred to the worked layer on the substrate 1. In the worked layer working step, it is possible to obtain (form) a worked layer 6 with a pattern shape by etching the worked layer on the substrate 1 using the inverted pattern 14 formed in the remaining film etching step as a working mask. FIG. 5E illustrates a state where the worked layer 6 has been formed.

FIG. 5F is a schematic diagram illustrating an inverted pattern removal step. The inverted pattern removal step is a final step of the inversion process step performed after the worked layer working step. In the inverted pattern removal step, the inverted pattern 14 that is a working mask is removed after the worked layer on the substrate 1 is worked.

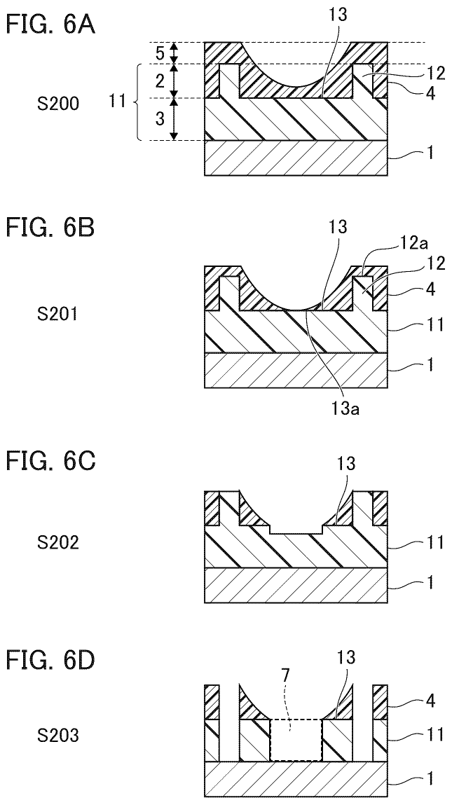

In the inversion process step, it may not be possible to form a desired inverted pattern depending on the projecting and recessed shape of the projecting and recessed pattern 2 of the cured film 11 and formation conditions of the inversion layer 4 as described above. Adverse effects will be described using FIG. 6. FIG. 6 is a schematic diagram for explaining the adverse effects that may occur in the inversion process step. FIG. 6A is a schematic diagram illustrating an inversion layer formation step S200. As in a case where the projecting and recessed shape of the projecting and recessed pattern 2 is large, the inversion layer 4 may not be uniformly formed as illustrated in FIG. 6A, and the film thickness of the inversion layer 4 formed on the projecting portion 12 of the projecting and recessed pattern 2 may become excessively thicker than the film thickness of the inversion layer 4 formed on the recessed portion 13.

FIG. 6B is a schematic diagram illustrating an excess inversion layer removal step 201. The excess inversion layer removal step 201 is performed after the inversion layer formation step S200. If the processing proceeds to the excess inversion layer removal step 201 which is the next step in the state illustrated in FIG. 6A, then the cured film 11 on the bottom surface 13a of the recessed portion 13 may be exposed earlier than the excess inversion layer 5 is completely removed to expose the top surface 12a of the projecting portion 12. If it is attempted to further remove the excess inversion layer 5 to expose the top surface 12a of the projecting portion 12 of the cured film 11, the cured film 11 made of the curable composition in the recessed portion 13 may be lost as illustrated in the excess inversion layer removal step 202 in FIG. 6C.

Also, since there is no inversion layer 4 as a mask that is supposed to be present in the recessed portion 13 in the remaining film etching step 203 illustrated in FIG. 6D, which is to be performed thereafter, the curable composition (cured film 11) does not remain at a location 7 where the curable composition is supposed to remain, and it is not possible to form a desired inverted pattern. Since such a situation may occur, it is desirable that the inversion layer 4 be smoothed and formed on the cured film 11.

### <Initial Cured Film Formation Step>

Next, the optical nanoimprint method used in the initial cured film formation step in the present embodiment will be described. According to the optical nanoimprint method, an initial cured film with a desired shape is formed on the substrate through roughly four steps. Specifically, a curable composition is applied (supplied) to a pattern formation region on the substrate first (arrangement step). Next, the curable composition is molded using a mold with a pattern formed therein (mold contact step). Then, the curable composition is irradiated with light and is thereby cured (light irradiation step). Thereafter, the mold is released (mold release step).

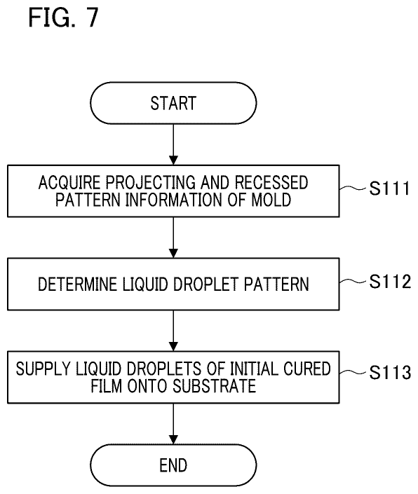

Here, the arrangement step will be described in detail. FIG. 7 is a flowchart for explaining the arrangement step. Although there are a spin coating method, an inkjet method, and the like as ways to apply the curable composition in the arrangement step, application by the inkjet method is performed as an example in the present embodiment. In the present embodiment, a pattern of liquid droplets to be applied to the substrate is caused to have a distribution to be suitable for the volume of the minute projecting and recessed pattern on the surface that the mold to be brought into contact in the mold contact step as a next step has, at the time of the application. Therefore, projecting and recessed pattern information of a mold 9 is acquired in S111. Thereafter, a processing unit that a working apparatus (a semiconductor manufacturing apparatus, an imprint apparatus), which is not illustrated, has determines the liquid droplet pattern in S112. Specifically, in S112, arrangement of the liquid droplet pattern is determined such that it is possible to supply the curable composition corresponding to the volume obtained by adding the volume of remaining film 3 to the volume of the projecting and recessed pattern 2 in accordance with each pattern position of the mold using the projecting and recessed pattern information of the mold 9 acquired in S111. It is desirable to do so because the thickness of the remaining film of the initial cured film formed becomes constant in the mold. Then, in S113, liquid droplets of the initial cured film are supplied onto the substrate 1 using the liquid droplet pattern determined in S112. Note that the liquid droplet pattern is information indicating the alignment (arrangement) of the liquid droplets of the curable composition to be arranged on the substrate 1 and may include information such as a volume of the liquid droplets, shape parameters of the liquid droplets, and the like.

Note that the processing unit may be configured of a computer including, for example, processor such as a central processing unit (CPU) and a storage unit such as a memory. The processing unit collectively controls each component of the working apparatus in accordance with various programs stored in the storage unit and performs the initial cured film formation step.

Note that although the liquid droplet pattern is simply determined on the basis of the sum of the volume of the projecting and recessed pattern of the mold and the volume of the remaining film here, the present invention is not limited thereto, and the liquid droplet pattern may be determined inconsideration of the shape of the projecting and recessed pattern of the mold 9 and the positions inside the mold, such as an outer side of the center.

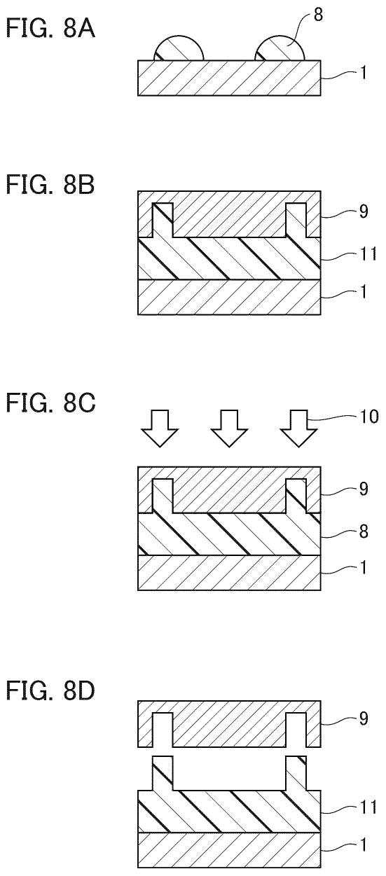

FIG. 8 is a schematic diagram for explaining an optical nanoimprint method. FIG. 8A is a schematic diagram illustrating the arrangement step. In the arrangement step, the liquid droplets of the curable composition 8 are arranged on (supplied to) the substrate 1 as described above.

FIG. 8B is a schematic diagram illustrating a mold contact step. In the mold contact step, the curable composition 8 and the mold 9 are brought into contact with each other. The contact step includes a step of changing a state where the curable composition 8 and the mold 9 are not in contact with each other (not illustrated) to a state where both the curable composition 8 and the mold 9 are in contact with each other and a step of maintaining the state where both the curable composition 8 and the mold 9 are in contact with each other. FIG. 8B illustrates a state where the curable composition 8 and the mold 9 are in contact with each other. The recessed portion of the minute pattern that the mold 9 has on its surface is filled with a liquid of the curable composition by maintaining the state where the curable composition 8 and the mold 9 are in contact with each other, and such a liquid becomes a liquid film with which the minute pattern of the mold 9 is filled.

As the mold 9, a mold constituted by a light transmitting material is used. Specific examples of a preferable material constituting the mold 9 include glass, quartz, PMMA, a light transparent resin such as a polycarbonate resin, a transparent metal deposited film, a soft film such as polydimethylsiloxane, a photocurable film, a metal film, and the like. However, in a case where a light transparent resin is used as a material constituting the mold 9, a resin that is not dissolved in components contained in the curable composition is selected. Quartz is desirable as a material constituting the mold because of its small pattern distortion. The pattern formed on the surface of the mold 9 has a height of equal to or greater than 4 nm and equal to or less than 200 nm, for example. As the height of the pattern of the mold 9 (the height of the projecting portion) is lower, a force of releasing the mold 9 from the cured film of the curable composition, that is, a mold release force can be reduced in the mold release step, and it is possible to reduce the number of mold release failures in which the pattern of the curable composition is torn apart and remains in the mold 9. Also, the pattern of the curable composition may be elastically deformed due to impact at the time of releasing the mold 9, adjacent pattern elements may be brought into contact with each other and cause adhesion or breakage. It is advantageous that the height of the pattern elements is equal to or less than about double (the aspect ratio is equal to or less than two) the widths of the pattern elements in order to avoid such disadvantages. On the other hand, excessively low heights of the pattern elements may lead to degradation of working accuracy of the substrate.

Surface treatment may be performed on the mold 9 before the contact step is performed in order to improve peelability of the mold 9 with respect to the curable composition. Examples of the surface treatment include treatment of applying a mold release agent to the surface of the mold 9 and forming a mold release agent layer. Examples of the mold release agent to be applied to the surface of the mold 9 include a silicon-based mold release agent, a fluorine-based mold release agent, a hydrocarbon-based mold release agent, a polyethylene-based mold release agent, a polypropylene-based mold release agent, a paraffine-based mold release agent, a montan-based mold release agent, a carnauba-based mold release agent, and the like. For example, a commercially available application-type mold release agent such as Optool (registered trademark) DSX manufactured by Daikin Industries, Ltd. can also suitably be used. Note that one kind of mold release agent may be used alone or two or more kinds of mold release agents may be used together. From among the aforementioned mold release agents, a fluorine-based mold release agent and the hydrocarbon-based mold release agent are particularly preferably used.

In the contact step, the pressure to be applied to the curable composition 8 when the mold 9 is brought into contact with the curable composition 8 is not particularly limited and is, for example, equal to or greater than 0 MPa and equal to or less than 100 Mpa. Note that the pressure to be applied to the curable composition 8 when the mold 9 is brought into contact with the curable composition 8 is preferably equal to or greater than 0 MPa and equal to or less than 50 MPa, is more preferably equal to or greater than 0 MPa and equal to or less than 30 MPa, and is further preferably equal to or greater than 0 MPa and equal to or less than 20 MPa. Although the contact step can be performed in any of the conditions, namely in an ambient atmosphere, in a reduced-pressure atmosphere, and an inert gas atmosphere, the contact step is preferably performed in the reduced-pressure atmosphere or in the inert gas atmosphere since it is possible to prevent influences of oxygen and moisture on the curing reaction. Specific examples of inert gas used in the case where the contact step is performed in the inert gas atmosphere include nitrogen, carbon dioxide, helium, argon, various kinds of freon gas, and mixed gas thereof. In a case where the contact step is performed in an atmosphere of specific gas including the ambient atmosphere, the preferable pressure is equal to or greater than 0.0001 atm and equal to or less than 10 atm.

FIG. 8C is a schematic diagram illustrating a curing step. In the curing step, the curable composition 8 is cured by irradiating the curable composition 8 with irradiation light 10 as curing energy to thereby form the cured film 11. In the curing step, the curable composition 8 is irradiated with the irradiation light 10 via the mold 9, for example. More specifically, the curable composition 8 with which the minute pattern of the mold 9 is filled is irradiated with the irradiation light 10 via the mold 9. In this manner, the curable composition 8 with which the minute pattern of the mold 9 is filled is cured to thereby form the cured film 11 with the pattern.

The irradiation light 10 is selected in accordance with a sensitive wavelength of the curable composition 8. Specifically, the irradiation light 10 is appropriately selected from ultraviolet light, X rays, or electron beams with a wavelength of equal to or greater than 150 nm and equal to or less than 400 nm. Note that the irradiation light 10 is particularly preferably ultraviolet light. This is because many commercially available curing aids (photopolymerization initiators) are compounds with sensitivity to ultraviolet light.

Examples of a light source that emits the ultraviolet light include a high-pressure mercury lamp, an ultra-high-pressure mercury lamp, a low-pressure mercury lamp, a deep-UV lamp, a carbon arc lamp, a chemical lamp, a metal halide lamp, a xenon lamp, a KrF excimer laser, an ArF excimer laser, an F2 laser, and the like. However, an ultra-high-pressure mercury lamp is particularly preferably used as the light source that emits ultraviolet light. The number of light sources may be one or more.

Also, the entire region of the curable composition 8 with which the minute pattern of the mold 9 is filled may be irradiated with the light, or only a partial region may be irradiated with the light (by limiting the region). Also, the irradiation with the light may be intermittently performed over the entire region of the substrate 1 a plurality of times or may be continuously performed on the entire region of the substrate 1. Furthermore, a first region of the substrate 1 may be irradiated with the light in a first irradiation procedure, and a second region that is different from the first region of the substrate may be irradiated with the light in a second irradiation procedure.

FIG. 8D is a schematic diagram illustrating a mold release step. In the mold release step, the mold 9 is released from the cured film 11 which is the curable composition 8 that has been cured. The cured film 11 with the pattern obtained by inverting the minute pattern of the mold 9 is obtained in a self-support state by releasing the mold 9 from the cured film 11 with the pattern. Any method can be used as a method of releasing the mold 9 from the cured film 11 with the pattern as long as a part of the cured film with the pattern is not physically damaged at the time of the releasing, and various conditions and the like are also not particularly limited. For example, the substrate 1 may be fixed, and the mold 9 may be caused to move away from the substrate 1. Alternatively, the mold 9 may be fixed, and the substrate 1 may be caused to move away from the mold 9. The mold 9 may be released from the cured film 11 with the pattern by causing both the mold 9 and the substrate 1 to move in opposite directions.

It is possible to obtain the cured film 11 having a projecting and recessed pattern with a desired shape (the pattern shape following the projecting and recessed shape of the mold) at a desired position through a series of steps including the aforementioned arrangement step to mold release step in this order. In the initial cured film formation step in the present embodiment, a repetition unit (shot) from the arrangement step to the mold release step is repeatedly performed a plurality of times on the same substrate, and the cured film with a plurality of desired patterns at desired positions on the substrate can thus be obtained.

### First Embodiment

Hereinafter, a pattern formation method (pattern working method) according to a first embodiment will be described in detail. In the present embodiment, an inversion layer with a two-layer configuration is adopted, and etching is performed thereon at substantially equal rates.

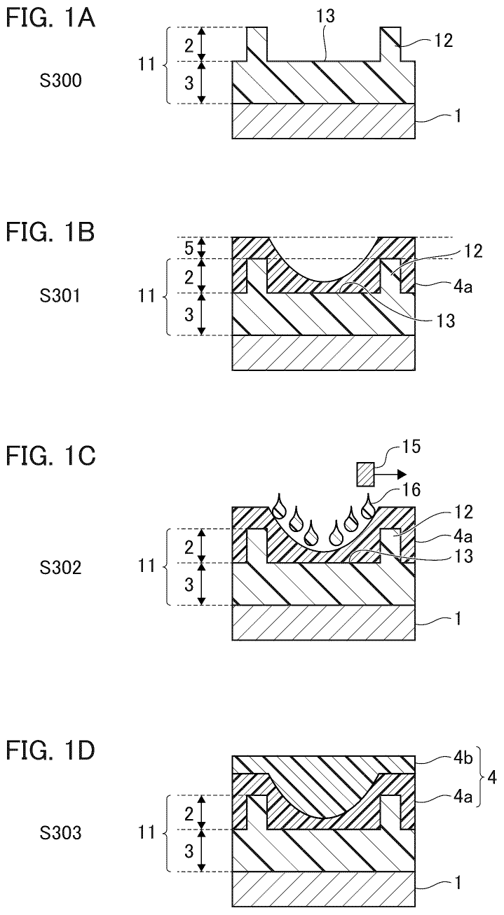

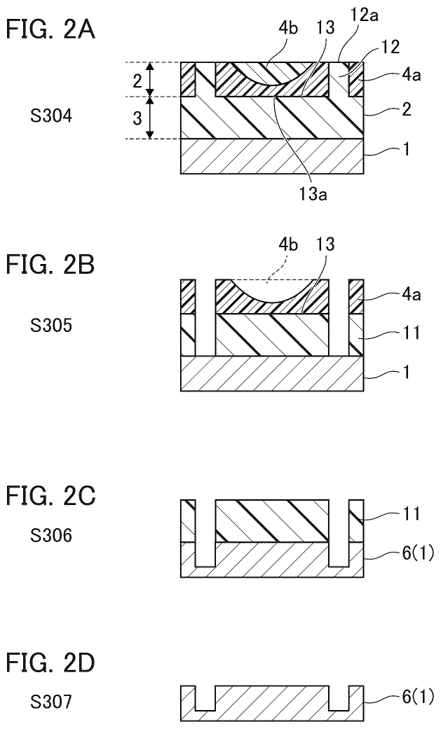

FIGS. 1 and 2 are schematic diagrams illustrating a flow of inversion process steps according to the first embodiment. FIG. 1A is a schematic diagram illustrating an initial cured film formation step S300 according to the first embodiment. Since the initial cured film formation step S300 according to the present embodiment is similar to the initial cured film formation step in the known inversion process steps described above, description thereof will be omitted.

FIG. 1B is a schematic diagram illustrating an inversion layer formation step S301 according to the first embodiment. In the inversion layer formation step according to the present embodiment, an inversion layer with a two-layer configuration are formed unlike the aforementioned known inversion layer formation step. Specifically, a first inversion layer 4a is formed on a cured film 11 with a projecting and recessed pattern 2 formed in the initial cured film formation step S300 first. In the present embodiment, a material containing 10% by weight or more of inorganic element is used as a material of the first inversion layer 4a. It is possible to express a sufficient etching selection ratio between itself and the cured film 11 with the projecting and recessed pattern 2 by containing 10% by weight or more of inorganic element.

Specifically, it is possible to select the material of the first inversion layer 4a from silicon-based materials such as SiO2 and SiN, organic materials containing silicon, metal oxide film materials such as TiO2 and Al2O3, typical metal materials, and the like. Examples of a method of forming the inversion layer of an organic material containing silicon include spin coating using spin on glass (SOG). Also, formation of the inversion layer made of SiO2 includes plasma CVD film formation using tetra ethyl ortho silicate (TEOS). In the present embodiment, the first inversion layer 4a is obtained by applying T-111 manufactured by Honeywell through spin coating.

Although some examples of the method of forming the first inversion layer 4a are listed, projections and recesses have influences in a case where the projecting and recessed shape of the cured film 11 is large regardless of which of the methods is adopted including the present embodiment, and it is difficult to smoothly form the first inversion layer 4a. Therefore, the first inversion layer 4a is likely to be non-uniformly formed as illustrated in FIG. 1B. Also, if the processing proceeds to the next step as it is, it is not possible to form a desired inverted pattern as described above, which is not desirable.

On the contrary, smoothness is achieved by forming a flattened inversion layer 4b as a second inversion layer on the first inversion layer 4a which is not uniform, in other words, which is not smooth in the present embodiment. In other words, the inversion layer 4 according to the present embodiment includes the first inversion layer 4a and the second inversion layer (flattened inversion layer 4b).

FIG. 1C is a schematic diagram illustrating an inversion layer formation step S302 according to the first embodiment. In the present embodiment, liquid droplets 16 of a material of the flattened inversion layer (flattened layer material, second inversion material) is discretely supplied from an inkjet nozzle 15 in accordance with the projections and recesses of the cured film 11 in the inversion layer formation step S302. In other words, a liquid droplet pattern is caused to have a distribution such that the volume of the flattened layer material arranged at the location corresponding to the recessed portion 13 of the projecting and recessed pattern 2 is greater than that arranged at the location corresponding to the projecting portion 12 of the projecting and recessed pattern 2. It is possible to control the amount of supplied or applied flattened layer material in accordance with a pattern density and the like of the projecting and recessed pattern 2 of the cured film 11 by forming the flattened inversion layer 4b by the inkjet method.

After the liquid droplets 16 of the flattened layer material is ejected from the inkjet nozzle 15 onto the first inversion layer 4a by the inkjet method, the liquid droplets 16 spread, the distances between the liquid droplets 16 approach, or the liquid droplets 16 are connected to form a continuous liquid film, on the first inversion layer 4a. Then, the smoothed film is formed on the cured film 11 by a solvent in the liquid film being volatilized. Therefore, according to the present method, it is possible to easily smooth the inversion layer 4.

In the present embodiment, a photocurable composition (b) that is cured through irradiation with light is used as the flattened layer material as will be described below. Therefore, the curable composition (b) is cured by irradiating it with light with a desired wavelength after the curable composition (b) is applied. The photocurable composition (b) in the present embodiment is prepared by blending a component (A) and a component (B) described below and filtering them with a 0.2 μm ultra-high molecular weight polyethylene filter.

The mole fraction weighted average molecular weight of the component (A) is 212.24.

### (1-1) Component (A): Total of 100 Parts by Weight

<A-1>Neopentyl glycol diacrylate (manufactured by Kyoeisha Chemical Co., Ltd., product name: NP-A, molecular weight: 212.24): 100 parts by weight

### (1-2) Component (B): Total of 3 Parts by Weight

<B-1>Lucirin (registered trademark) TPO (manufactured by BASF): 3 parts by weight

The viscosity of the thus prepared photocurable composition at 25° C. measured using a conical flat plate rotation viscometer RE-85L (manufactured by Toki Sangyo) is 5.33 mPa·s, which is a viscosity suitable for use in the inkjet method.

FIG. 1D is a schematic diagram illustrating an inversion layer formation step S303 according to the first embodiment. As described above, the curable composition (b) has a viscosity suitable for the inkjet method, and the inversion layer 4 is thus smoothly formed by the flattened inversion layer 4b in the inversion layer formation step S303 according to the present embodiment. Also, although the photocurable composition is used in the present embodiment, the present invention is not limited thereto, and it is also possible to use a thermosetting composition or the like. As a material to be used, a composition containing at least a polymerizable compound and a polymerization initiator and further containing a non-polymerizable compound or a solvent as needed is preferably used. A material with a viscosity of 1 mPa·s to 30 Pa·s (25° C.) is preferably used, or a material with a viscosity of 1 mPas to 20 mPa·s (25° C.) is more preferably used. There is a concern that it may be difficult to form the liquid droplets if the viscosity (25° C.) is less than 1 mPa·s, and there is a concern that it may be difficult to eject (or form) the liquid droplets if the viscosity (25° C.) exceeds 30 Pa·s. At this time, the non-polymerizable compound is at least one kind selected from a group consisting of a sensitizer, a hydrogen donor, an internal mold release agent, a surfactant, an antioxidant, a polymer component, and the like.

FIG. 2A is a schematic diagram illustrating an excess inversion layer removal step S304 according to the first embodiment. In the present embodiment, the first inversion layer 4a and the flattened inversion layer 4b are etched at substantially equal etching rates in the excess inversion layer removal step S304. Here, although it is only necessary for the etching rates to be etching rates at which the top surface 12a of the projecting portion 12 of the projecting and recessed pattern 2 is exposed earlier than the bottom surface 13a of the recessed portion 13 of the projecting and recessed pattern 2, it is further desirable that the etching rates of the first inversion layer 4a and the flattened inversion layer 4b be equal to each other. As described above, there has been a problem that the bottom surface 13a of the recessed portion 13 is exposed earlier than the excess inversion layer 5 is completely removed to expose the top surface 12a of the projecting portion 12 and the mask material needed in the following step is not present in the recessed portion of the projecting and recessed pattern 2 in the related art. In the present embodiment, the flattened inversion layer is etched at the etching rate at which the top surface 12a of the projecting portion 12 of the projecting and recessed pattern 2 is exposed earlier than the bottom surface 13a of the recessed portion 13 of the projecting and recessed pattern 2. Therefore, such a situation in which the mask material needed in the following step is not present in the recessed portion 13 does not occur. In the present embodiment, the surface of the inversion layer 4 is smoothed in the inversion layer formation step S303. Therefore, the top surface 12a of the projecting portion 12 of the projecting and recessed pattern 2 is exposed earlier than the bottom surface 13a of the recessed portion 13 of the projecting and recessed pattern 2 by etching the first inversion layer 4a and the flattened inversion layer 4b at the substantially equal rates. Also, it is possible to remove the inversion layer 4 in a smooth state as described in the excess inversion layer removal step S304.

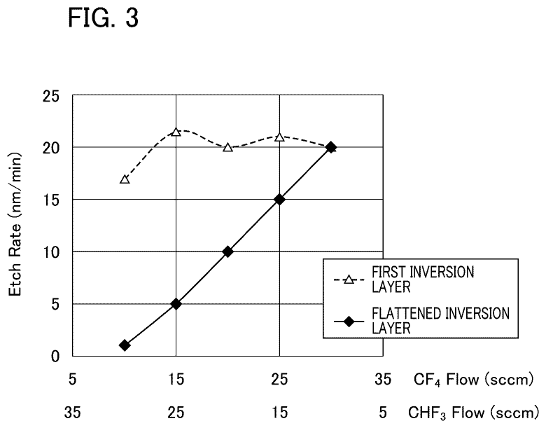

In the present embodiment, etching is performed by mixing a plurality of kinds of etching gas by a plasma etching apparatus. The plurality of kinds of etching gas include gas containing a chain hydrocarbon compound represented as CₓH_{y}F_{z} (C represents carbon, H represents hydrogen, F represents fluorine, and x, y, and z each represent an integer that is equal to or greater than one) and fluorocarbon compound gas represented as CₐF_{b} (a and b each represent an integer that is equal to or greater than one). Here, etching is performed using Ar, CF₄, and CHF₃ as etching gas. FIG. 3 is a diagram illustrating an example of an etching rate with respect to a mixing ratio of the etching gas in the first embodiment. Specifically, the drawing illustrates an etching rate of each of the first inversion layer 4a and the flattened inversion layer 4b in the present embodiment with respect to a mixing ratio of the etching gas CF₄ and CHF₃. The vertical axis of the drawing represents the etching rate, and the horizontal axis represents the flow amount of each of CF₄ and CHF₃. At this time, Ar is constant at 50 sccm.

In the present embodiment, etching is performed under a condition that the etching rates of the first inversion layer 4a and the flattened inversion layer 4b are the closest, or preferably under a condition that the etching rates thereof become the same. It is possible to ascertain from FIG. 3 that the etching rates of the first inversion layer 4a (here, SiO₂) and the flattened inversion layer 4b (here, the photocurable composition (b)) become the same when Ar=50 sccm, CF₄=30 sccm, and CHF₃=10 sccm. It is possible to etch each layer at substantially equal rates by performing the etching under the condition.

Although it is possible to perform the etching at the substantially equal rates at the above gas mixing ratio as an example here, kinds and ratios of the gas needed differ depending on the materials to be used, and adjustment and consideration are thus needed depending on each condition. However, as long as such materials as described in the present embodiment are used as the first inversion layer material and the flattened layer material, it is possible to etch each layer at substantially equal rates by adjusting the mixing ratio even if the kinds and the like of used gas change. At least options of the first inversion layer material and the flattened layer material that enable etching at substantially equal rates through adjustment of the mixing ratio of gas are wider than those of materials that have sufficient etching selection ratio between themselves and the cured film when used alone and have viscosities with which the materials are easily smoothed. Therefore, since each feature can be focused on each layer in development of new materials, development can be carried out with a high degree of freedom, this may lead to cost reduction, and these advantages of the present embodiment are significant.

Note that etching gas containing halogen can be used as the etching gas, and specifically, it is possible to use etching gas containing one or more of fluorine, chlorine, and bromine. For example, it is possible to use C₅F₆, CF₄, SF₆, CHF₃, CH₂F₂, Cl₂, BCl₃, SiCl₄, CCl₄, PCl₃, SF₆, BBr₃, or the like alone or to mix and use two or more kinds therefrom as the etching gas. Also, it is possible to appropriately add oxygen gas, carbon dioxide gas, nitrogen gas, helium gas, argon gas, hydrogen gas, hydrocarbon gas, or the like to the above etching gas. Moreover, it is also possible to use gas containing hydrocarbon gas or hydrogen gas as the etching gas. As hydrocarbon used in the etching gas, it is possible to use one or more of methane (CH₄), ethane (C₂H₆), propane (C₃H₈), butane (C₄H₁₀), ethylene (C₂H₄), propylene (C₃H₆), acetylene (C₂H₂), and propyne (C₃H₄). Furthermore, it is also possible to use fluorocarbon-based gas such as CF₄, CHF₄, C₂F₆, C₃F₈, C₄F₈, C₅F₈, C₄F₆, CCl₂F₂, CBrF₃, or the like as the etching gas. Note that these kinds of gas may be mixed and used.

Referring again to FIG. 2, a remaining film etching step S305 is then performed. FIG. 2B is a schematic diagram illustrating the remaining film etching step S305 according to the first embodiment. Here, since a curable resin used as a flattened layer material has substantially the same composition as the curable resin constituting the initial cured film, the flattened inversion layer 4b is removed at the same time in the remaining film etching step S305. However, the first inversion layer 4a remains in the recessed portion 13. In other words, a state where the flattened inversion layer 4b is removed from the recessed portion 13 and the first inversion layer 4a remains as illustrated in FIG. 2B is achieved. In this state, the cured film 11 that is supposed to remain is not lost in the remaining film etching step.

Thereafter, a worked layer working step S306 is performed. FIG. 2C is a schematic diagram illustrating the worked layer working step S306 according to the first embodiment. In the worked layer working step S306, it is possible to etch the worked layer on the substrate 1 using the inverted pattern as a working mask and to obtain (form) the worked layer 6 with the pattern shape since the desired inverted pattern (cured film 11) remains in the remaining film etching step S305.

FIG. 2D is a schematic diagram illustrating an inverted pattern removal step S307 according to the first embodiment. After the worked layer working step S306, the inverted pattern as the working mask is removed after the worked layer on the substrate 1 is worked in the inverted pattern removal step S307. It is thus possible to form the desired pattern on the worked layer.

As described above, the first inversion layer 4a and the flattened inversion layer 4b as the second inversion layer thereon to smooth the inversion layer 4 are formed in the inversion process steps in the present embodiment. Also, it is possible to obtain a desired pattern in the worked layer with a high degree of freedom in selecting the inversion layer materials by etching the first inversion layer 4a and the flattened inversion layer 4b at substantially equal rates.

Although the photocurable composition (b) is used as the flattened layer material in the present embodiment, a curable composition including a polymerizable compound, a photopolymerization initiator, and a solvent may be used. Here, the polymerizable compound preferably contains at least a compound having an aromatic structure, an aromatic heterocycle structure, or an alicyclic structure. Also, the curable composition preferably has a viscosity of equal to or greater than 2 mPas and equal to or less than 60 mPas at 23° C. Also, a curable composition, which has a viscosity of equal to or greater than 30 mPas and equal to or less than 10,000 mPas at 23° C. in a state where the solvent is removed, in which the content of solvent with respect to the entire curable composition is equal to or greater than 70% by volume and equal to or less than 95% by volume may be used. In this case, since the liquid droplets of the flattened layer material are likely to be connected and are likely to form a substantially continuous liquid film, and it becomes easier to form a smoother inversion layer.

Furthermore, although the example in which the curing is performed right after the application when the flattened inversion layer is formed has been described in the present embodiment, the flattened inversion layer 4b may be smoothed using a mold (flat plate) with a flat (smooth) surface after the inversion layer formation step 302. Specifically, after the flattened layer material is ejected by the inkjet method, the flat surface of the flat plate is pressed against the flattened layer material. Then, the flattened layer material is cured, and the flat plate is released. It is easy to form a smoother inversion layer in this case as well.

Also, although the example in which the inversion layer 4 is configured of the first inversion layer 4a and the flattened inversion layer 4b as the second inversion layer has been described in the present embodiment, the inversion layer 4 may include three or more layers. It is only necessary to adopt the etching rate at which the top surface 12a of the projecting portion 12 of the projecting and recessed pattern 2 is exposed earlier than the bottom surface 13a of the recessed portion 13 of the projecting and recessed pattern 2 in this case as well, and it is further desirable that etching rates of all the layers included in the inversion layer 4 be equal to each other. Alternatively, it is assumed that the inversion layer 4 includes the first inversion layer 4a and the flattened inversion layer 4b, and a second flattened inversion layer is further formed on the flattened inversion layer 4b, for example. Here, the flattened inversion layer 4b is defined as a first flattened inversion layer. In this case, the first flattened inversion layer and the second flattened inversion layer may be etched at substantially equal speeds, and the first flattened inversion layer and the first inversion layer may be etched at substantially equal speeds from the point at which the second flattened inversion layer is eliminated.

### Second Embodiment

Basic inversion process steps in the present embodiment are similar to those (the flow illustrated in FIGS. 1 and 2) in the first embodiment. The present embodiment is different from the first embodiment in the inversion layer formation step. The other steps are similar to those in the first embodiment, and description thereof will thus be omitted here.

In the inversion layer formation step according to the present embodiment, liquid droplets 16 of a flattened layer material are applied (supplied) onto a first inversion layer 4a by using the inkjet method similarly to the first embodiment described above. At this time, information regarding a liquid droplet pattern of a curable composition to be supplied onto a substrate at the time of an initial cured film formation step is referred to in regard to the application of the flattened layer material in the present embodiment. When a cured film 11 has a projecting and recessed pattern 2, and a material of a first inversion layer is applied by the method as described in the first embodiment, a recessed portion 13 of the projecting and recessed pattern 2, that is, a projecting region of a mold is more likely to have a recessed shape in the first inversion layer. Also, a projecting portion 12 of the projecting and recessed pattern 2, that is, a recessed portion of the mold is more likely to have a projecting shape in the first inversion layer.

Therefore, there is a relevance between the amount of applied (amount of supplied) curable composition at the time of the initial cured film formation step and the amount of applied (amount of supplied) flattened layer material needed to achieve smoothness. Therefore, the liquid droplet pattern of the flattened inversion layer material is determined by uniformly subtracting the volume of the remaining film 3 from the liquid droplet pattern of the curable composition arranged on the substrate 1 at the time of the initial cured film formation step in the present embodiment. The inversion layer is then smoothed by applying the determined liquid droplet pattern. It is desirable to perform calculation with reference to the liquid droplet pattern of the applied curable composition at the time of the initial cured film formation step since it is possible to more efficiently determine the liquid droplet pattern of the flattened layer material.

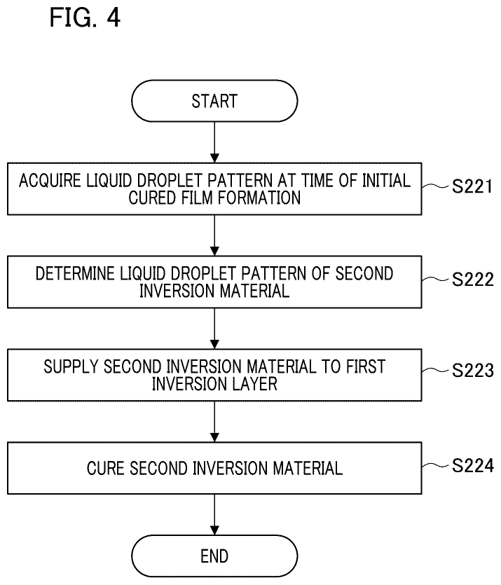

Here, the inversion layer formation step in the present embodiment will be described in detail using FIG. 4. FIG. 4 is a flowchart for explaining the inversion layer formation step according to the second embodiment. First, the liquid droplet pattern of the curable composition at the time of the initial cured film formation is acquired in S221.

Next, the liquid droplet pattern of the flattened layer material is determined in S222. Specifically, the liquid droplet pattern of the flattened inversion layer material is determined using a value obtained by subtracting the volume of the remaining film 3 from the liquid droplet pattern of the curable composition arranged on the substrate 1 at the time f the initial cured film formation acquired in S221. As described above, when the initial cured film has the projecting and recessed pattern 2, the recessed portion 13 of the projecting and recessed pattern 2, that is, the projecting region of the mold is more likely to have a recessed shape in the first inversion layer, and the projecting portion 12 of the projecting and recessed pattern 2, that is, the recessed portion of the mold is more likely to have a projecting shape in the first inversion layer. Therefore, the liquid droplet pattern is caused to have a distribution such that the volume of the flattened layer material arranged at the location corresponding to the recessed portion 13 of the projecting and recessed pattern 2 is greater than that arranged at the location corresponding to the projecting portion 12 of the projecting and recessed pattern 2, for example. In regard to this, the liquid droplet pattern may be caused have the distribution by increasing or decreasing the volume of one liquid droplet or by the arrangement density of the liquid droplets.

In S223, the liquid droplets of the flattened layer material are supplied (applied) onto the first inversion layer 4a using the liquid droplet pattern determined in S222. Then, the flattened layer material is cured in S224.

Note that design information of the mold used to form the initial cured film and/or information regarding the projecting and recessed pattern 2 of the cured film 11 may be used instead of or in addition to the information regarding the liquid droplet pattern of the curable composition at the time of the initial cured film formation step.

Also, the liquid droplet pattern of the flattened layer material may be determined by performing calculation with reference to the liquid droplet pattern of the curable composition at the time of the initial cured film formation step in consideration of each condition such as flowing of the liquid droplets of the flattened layer material in the vicinity of the projecting and recessed pattern 2, for example. Furthermore, if occurrence of variations (for example, the thickness at the outer periphery of the substrate 1 decreases) in the formation of the first inversion layer 4a is known in advance, such information may be taken into consideration. Moreover, there may be variations in manufacturing of the substrate 1 itself, and such variations may be further taken into consideration. The variations in manufacturing of the substrate 1 have similar trends for each lot. One lot includes a plurality of substrates.

Also, each of the materials described in the first embodiment can be used as the flattened layer material used in the present embodiment, and a curable method suitable therefor may be used in S224.

Furthermore, although the example in which the flattened layer material is cured right after the application has been described here, a flat surface of a flat plate may be pressed against the flattened layer material after the application of the flattened layer material to thereby smooth the flattened inversion layer similarly to the first embodiment.

As described above, according to the second embodiment, the liquid droplet pattern of the curable composition at the time of the initial cured film formation step is further referred to when the flattened layer material is applied, and the liquid droplet pattern of the flattened layer material is determined. It is thus possible to more efficiently determine the liquid droplet pattern when the flattened layer material is applied.

### <Method of Manufacturing Article>

The inverted pattern formed by the pattern formation method according to the present invention can be used as it is as a configuring member that is at least a part of various articles. Also, the inverted pattern is temporarily used as a working mask for etching, ion injection, and the like performed on a worked layer on a substrate. After etching, ion injection, or the like is performed on the worked layer in the process of working the worked layer on the substrate, the inverted pattern as the working mask is removed. In this manner, it is possible to manufacture various articles.

The articles are an electric circuit element, an optical element, an MEMS, a recording element, a sensor, a mold, or the like. Examples of the electric circuit element include volatile or non-volatile semiconductor memories such as a DRAM, an SRAM, a flash memory, and an MRAM, semiconductor elements such as an LSI, a CCD, an image sensor, and an FPGA, and the like. If the worked layer is provided as an insulating layer, it is possible to use the worked layer as an interlayer insulating film included in the semiconductor memories or semiconductor elements as described above.

It is also possible to obtain an optical element by using a worked layer with a pattern shape obtained through the initial cured film formation step to the inverted pattern removal step as an optical member such as a diffraction grating or a polarizing plate (including a case where it is used as one member of optical members). In such a case, it is possible to obtain an optical element including at least a substrate and a worked layer with a pattern shape on the substrate. Examples of the optical element include a microlens, a conductor, a waveguide, an anti-reflection film, a diffraction grating, a polarizing element, a color filter, a light-emitting element, a display, a solar battery, and the like.

Examples of the MEMS include a DMD, a micro-flow path, an electromechanical conversion element, and the like. Examples of the recording element include optical discs such as a CD and a DVD, a magnetic disk, a magnetooptical disc, a magnetic head, and the like. Examples of the sensor include a magnetic sensor, an optical sensor, a gyro sensor, and the like. Examples of the mold include a mold for imprinting.

While the present invention has been described with reference to exemplary embodiments, it is to be understood that the invention is not limited to the disclosed exemplary embodiments. The scope of the following claims is to be accorded the broadest interpretation to encompass all such modifications and equivalent structures and functions.

This application claims the benefit of priority from Japanese Patent Application No. 2024-020058, filed on Feb. 14, 2024, which is hereby incorporated by reference herein in its entirety.

What is claimed is:

1. A pattern formation method comprising:
forming a first inversion layer on a projecting and recessed pattern of a curable composition;
forming a flattened inversion layer as a second inversion layer on the first inversion layer;
performing first etching of etching an upper layer portion of an inversion layer including the first inversion layer and the flattened inversion layer to expose a top surface of a projecting portion of the projecting and recessed pattern; and
performing second etching of etching the exposed pattern of the curable composition using the inversion layer remaining in a recessed portion of the projecting and recessed pattern as a mask,
wherein in the first etching, the first inversion layer and the flattened inversion layer are etched using mixed gas obtained by a plurality of kinds of etching gas.

2. The pattern formation method according to claim 1, wherein a mixing ratio of the plurality of kinds of etching gas is a ratio to achieve an etching rate at which the top surface of the projecting portion of the projecting and recessed pattern is exposed earlier than a bottom surface of the recessed portion of the projecting and recessed pattern in the first etching.

3. The pattern formation method according to claim 1, wherein a mixing ratio of the plurality of kinds of etching gas is a ratio that enables the first inversion layer and the flattened inversion layer to be etched at substantially equal etching rates.

4. The pattern formation method according to claim 1, wherein the first inversion layer contains 10% by weight or more of inorganic element.

5. The pattern formation method according to claim 1, wherein the content of inorganic element in the curable composition is equal to or less than 1% by weight.

6. The pattern formation method according to claim 1, wherein the curable composition forming the projecting and recessed pattern is the same as a curable composition forming the flattened inversion layer.

7. The pattern formation method according to claim 1, wherein as the plurality of kinds of etching gas, etching gas containing a chain hydrocarbon compound represented as CₓH_{y}F_{z} (C represents carbon, H represents hydrogen, F represents fluorine, and x, y, and z each represent an integer that is equal to or greater than one) and fluorocarbon compound gas represented as CₐF_{b} (a and b each represent an integer that is equal to or greater than one) are included.

8. The pattern formation method according to claim 1, wherein the first inversion layer is formed by a spin coating method.

9. The pattern formation method according to claim 1, wherein the flattened inversion layer is formed by an inkjet method.

10. The pattern formation method according to claim 1, wherein when the second inversion layer is formed, the flattened inversion layer is formed by ejecting an inversion material of the flattened inversion layer onto the first inversion layer by an inkjet method and by liquid droplets of the inversion material then spreading, distances between the liquid droplets decreasing, or the liquid droplets being connected to form a continuous liquid film, and a solvent in the liquid film being volatilized.

11. The pattern formation method according to claim 1, wherein when the second inversion layer is formed, an inversion material of the flattened inversion layer is ejected by an inkjet method, a flat surface of a mold including the flat surface is then pressed against the inversion material, the inversion material is cured, and the flat mold is released.

12. The pattern formation method according to claim 1,
wherein the projecting and recessed pattern of the curable composition is formed using a mold,
liquid droplets of the curable composition are supplied onto a substrate in a liquid droplet pattern determined on the basis of the projecting and recessed pattern that the mold has when the projecting and recessed pattern is formed, and
when the flattened inversion layer is formed, liquid droplets of an inversion material are supplied onto the first inversion layer, and a liquid droplet pattern to be used at a time of supplying the inversion material is determined on the basis of the liquid droplet pattern of the curable composition.

13. A method of manufacturing an article comprising:
forming the pattern of the curable composition using the pattern formation method according to claim 1;
treating a substrate on which the pattern has been formed; and
manufacturing an article from the treated substrate.
